(19) United States
(12) Patent Application Publication
(10) Pub. No.: US 2019/0042047 A1
(43) Pub. Date: Feb. 7, 2019

(54) PIXEL ARRAY SUBSTRATE

(71) Applicant: Chunghwa Picture Tubes, LTD., Taoyuan City (TW)

(72) Inventors: Jhen-Shen Liao, Taoyuan City (TW); Hung-Hsiang Chen, Taoyuan City (TW)

(73) Assignee: Chunghwa Picture Tubes, LTD., Taoyuan City (TW)

(21) Appl. No.: 15/821,848

(22) Filed: Nov. 24, 2017

(30) Foreign Application Priority Data
Aug. 3, 2017 (CN) 201710654806.6

(51) Int. Cl. G06F 3/041; H01L 27/12

(52) U.S. Cl. CPC G06F 3/0416; G09G 5/003; H01L 27/124

(57) ABSTRACT

A pixel array substrate including a substrate divided into a pixel region and a peripheral region is provided. A plurality of active devices and a plurality of touch pads are disposed in the pixel region of the substrate. A plurality of gate lines, a plurality of data lines, a plurality of gate signal lines and a plurality of touch signal lines are disposed on the substrate. A gate driver, a source driver and a touch processing unit are disposed in the peripheral region of the substrate and located on a same side of the pixel region. The gate signal lines electrically connect the corresponding gate lines to the gate driver. The touch signal lines electrically connect the corresponding touch pads to the touch processing unit. Portions of the data lines, the gate signal lines and the touch signal lines within the pixel region are parallel to each other.

### CROSS-REFERENCE TO RELATED APPLICATION

This application claims the priority benefit of China application serial no. 201710654806.6, filed on Aug. 3, 2017. The entirety of the above-mentioned patent application is hereby incorporated by reference herein and made a part of this specification.

### BACKGROUND OF THE INVENTION

### 1. Field of the Invention

The invention relates to an array substrate, and more particularly, to a pixel array substrate.

### 2. Description of Related Art

With the diversification in display technology development, electronic products have ever-increasing demand for more effective use efficiency on screen display region. Therefore, display devices with a narrow border have been constantly renewed. In the current display devices, a display region is equivalent to a pixel region on a pixel array substrate, and a border region is equivalent to a peripheral region outside the pixel region. In general, the peripheral region is a space for disposing various elements, drivers, wirings, etc. In addition, in order to realize slimness for a display device and a touch device, designs that integrate touch functions into the display device have been proposed. Nonetheless, with the ongoing trend for reducing the border region, how to dispose the elements, the drivers and the wirings while integrating the touch functions altogether has become one of the important issues to be addressed by the industry.

### SUMMARY OF THE INVENTION

The invention is directed to a pixel array substrate, which is capable of realizing the narrow border.

According to embodiments of the invention, a pixel array substrate includes a substrate, a plurality of active devices, a plurality of touch pads, a plurality of gate lines, a plurality of data lines, a plurality of gate signal lines, a plurality of touch signal lines, a gate driver, a source driver and a touch processing unit. The substrate is divided into a pixel region and a peripheral region. The active devices and the touch pads are disposed in the pixel region of the substrate. The gate lines, the data lines, the gate signal lines and the touch signal lines are disposed on the substrate. The gate driver, the source driver and the touch processing unit are disposed in the peripheral region of the substrate and located on a same side of the pixel region. The gate lines and the data lines are electrically connected to the corresponding active devices, respectively. The data lines are electrically connected to the source driver. The gate signal lines electrically connect the corresponding gate lines to the gate driver. The touch signal lines electrically connect the corresponding touch pads to the touch processing unit. Portions of the data lines, the gate signal lines and the touch signal lines within the pixel region are parallel to each other.

In the pixel array substrate according to the embodiments of the invention, the touch processing unit may be disposed between two said source drivers, and the source driver may be disposed between two said gate drivers.

In the pixel array substrate according to the embodiments of the invention, a number of the gate signal lines may be less than a number of the data lines.

In the pixel array substrate according to the embodiments of the invention, a number of the touch signal lines may be less than a number of the gate signal lines.

In the pixel array substrate according to the embodiments of the invention, the touch signal lines and the gate signal lines may be respectively adjacent to the different data lines.

In the pixel array substrate according to the embodiments of the invention, the touch signal lines and a part of the gate signal lines may be respectively adjacent to the same data lines.

In the pixel array substrate according to the embodiments of the invention, a part of the gate signal lines may be connected to each other in the peripheral region before being connected to the gate driver.

In the pixel array substrate according to the embodiments of the invention, a part of the touch signal lines may be connected to each other in the peripheral region before being connected to the touch processing unit.

In the pixel array substrate according to the embodiments of the invention, the pixel array substrate may further include a plurality of dummy signal lines disposed on the substrate. The dummy signal lines are parallel to the gate signal lines. A total number of the dummy signal lines and the gate signal lines is equal to a number of the data lines, and the dummy signal lines and the gate signal lines are commonly equidistantly distributed on the substrate.

In the pixel array substrate according to the embodiments of the invention, the source driver and the touch processing unit may be integrated into a single electronic device.

In the pixel array substrate according to the embodiments of the invention, the data lines, the gate signal lines and the touch signal lines may be respectively located on different layers.

In the pixel array substrate according to the embodiments of the invention, at least two of the data lines, the gate signal lines and the touch signal lines may be located on a same layer.

In the pixel array substrate according to the embodiments of the invention, the gate driver, the source driver and the touch processing unit may be synchronized by a synchronizing signal.

Based on the above, in the pixel array substrate according to the embodiments of the invention, the gate driver, the source driver and the touch processing unit are disposed in the peripheral region and located on the same side of the pixel region, and the portions of the data lines, the gate signal lines and the touch signal lines within the pixel region are parallel to each other. Accordingly, other than the effectiveness that the touch processing unit and the touch signal lines can be integrated into the processing unit, the opening rate and the narrow border may also be improved.

To make the above features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a pixel array substrate in the first embodiment of the invention.

FIG. 2 is a partial enlarged view of FIG. 1.

FIG. 3 is a partial schematic diagram of a pixel array substrate in the second embodiment of the invention.

FIG. 4 is a partial schematic diagram of a pixel array substrate in the third embodiment of the invention.

FIG. 5 is a partial schematic diagram of a pixel array substrate in the fourth embodiment of the invention.

FIG. 6A and FIG. 6B are schematic diagrams for disposing gate signal lines and data lines according to an embodiment of the invention.

FIG. 7A to FIG. 7C are schematic diagrams for disposing gate signal lines, touch signal lines and data lines according to an embodiment of the invention.

FIG. 8A to FIG. 8C are schematic diagrams for disposing dummy signal lines, touch signal lines and data lines according to an embodiment of the invention.

### DESCRIPTION OF THE EMBODIMENTS

Reference will now be made in detail to the present preferred embodiments of the invention, examples of which are illustrated in the accompanying drawings.

Wherever possible, the same reference numbers are used in the drawings and the description to refer to the same or like parts.

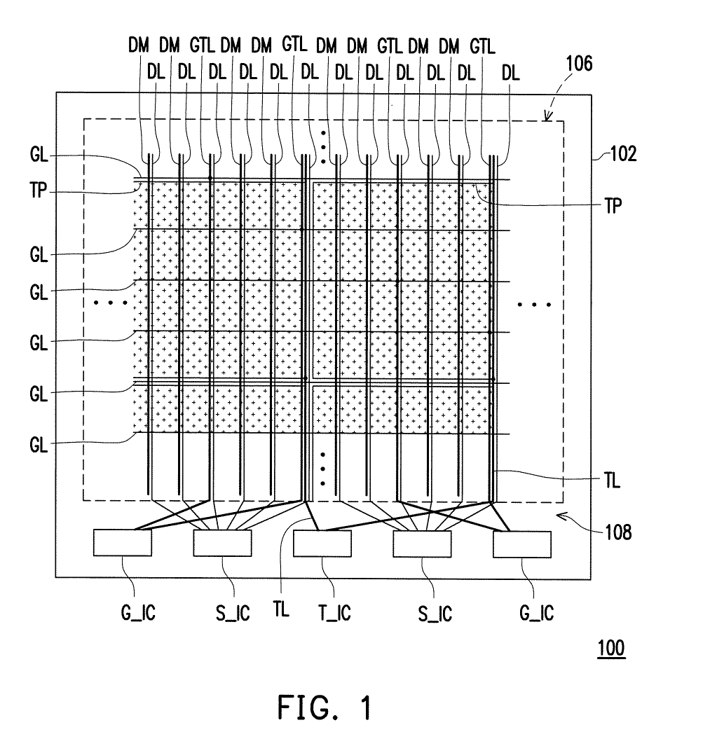

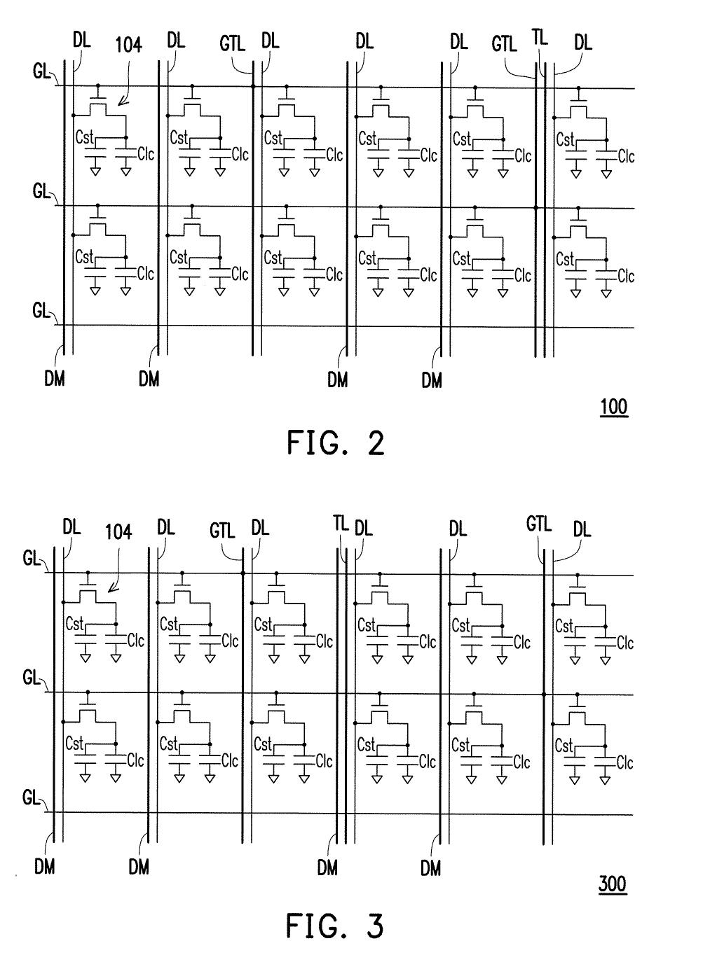

FIG. 1 is a schematic diagram of a pixel array substrate in the first embodiment of the invention. FIG. 2 is a partial enlarged view of FIG. 1.

The followings refer to FIG. 1 and FIG. 2 together. A pixel array substrate 100 includes a substrate 102, a plurality of active devices 104 (illustrated in FIG. 2), a plurality of touch pads TP, a plurality of gate lines GL, a plurality of data lines DL, a plurality of gate signal lines GTL, a plurality of touch signal lines TL, a gate driver G_IC, a source driver S_IC and a touch processing unit T_IC. The substrate 102 is divided into a pixel region 106 and a peripheral region 108.

The active devices 104 are disposed in the pixel region 106 of the substrate 102 and arranged in an array. The active device 104 is, for example, a thin film transistor including a gate, a source and a drain, wherein a liquid crystal capacitor C_{lc} and a storage capacitor Cₛₜ are electrically connected between the drain and a common electrode (not illustrated). The gate lines GL are disposed in the pixel region 106 of the substrate 102 and electrically connected to the gates of the corresponding active devices 104. The data lines DL are disposed on the substrate 102 and extend from the pixel region 106 to the peripheral region 108, such that the data line DL is electrically connected to the sources of the corresponding active devices 104 and one end of the data line DL is electrically connected to the source driver S_IC. The data lines DL and the gate lines GL within the pixel region 106 are intersected (e.g., perpendicularly intersected) to each other in form of a mesh, and the active device 104 is adjacent to an intersection between the data line DL and the gate line GL. The gate signal lines GTL are disposed on the substrate 102 and extend from the pixel region 106 to the peripheral region 108, such that the gate signal line GTL is electrically connected to the corresponding gate lines GL and one end of the gate signal line GTL is electrically connected to the gate driver G_IC. The gate signal lines GTL are parallel to the data lines DL within the pixel region 106. In an embodiment of the invention, a number of the gate signal lines GTL depends on a number of the gate lines GL, namely, the number of the gate signal lines GTL is equal to the number of the gate lines GL. Based on how the active devices 104 are arranged in the array, the number of the gate signal lines GTL may be less than a number of the data lines DL.

The touch pads TP are disposed in the pixel region 106 of the substrate 102 and arranged in an array. The touch signal lines TL are disposed on the substrate 102 and extend from the pixel region 106 to the peripheral region 108, such that the touch signal line TL is electrically connected to the corresponding touch pads TP and one end of the touch signal line TL is electrically connected to the touch processing unit T_IC. The touch signal lines TL and the touch pads TP may be located on a same layer and electrically connected to each other. However, the invention is not limited thereto. The touch signal lines TL and the touch pads TP may also be located on different layers and electrically connected to each other through contact holes. The touch signal lines TL are parallel to the data lines DL within the pixel region 106. In the present embodiment, an area covered by each touch pad TP may be selectively overlapping with multiple gate signal lines GTL, and an amount of such overlaps may be adjusted according to a touch sensing resolution. Therefore, a number of the touch signal lines TL may be less than the number of the gate signal lines GTL. It should be understood that, a size of the touch pad TP shown in FIG. 1 is only for illustrative purpose instead of limitation to the invention.

The gate driver G_IC, the source driver S_IC and the touch processing unit T_IC are disposed in the peripheral region 108 of the substrate 102 and located on a same side of the pixel region 106. There is no particular limitation on a packaging method for the gate driver G_IC, the source driver S_IC and the touch processing unit T_IC, which may be a chip on glass (COG) method or a chip on film (COF) method. In an embodiment of the invention, arrangement directions of the gate driver G_IC, the source driver S_IC and the touch processing unit T_IC are parallel to an extending direction of the gate lines GL. In an embodiment of the invention, numbers of the source driver S_IC and the gate driver G_IC are two or more, but the invention is not limited thereto. The touch processing unit T_IC is disposed between two said source drivers S_IC, and the source driver S_IC is disposed between two said gate drivers G_IC. Under the architecture of the present embodiment, a dimension of the peripheral region 108 may be reduced. For instance, two said gate drivers G_IC may be disposed in the peripheral region 108 in parallel with the extending direction of the gate lines GL, and the two said gate drivers G_IC can respectively provide signals for approximately half of the gate signal lines GTL. Two said source drivers S_IC are disposed between two said gate drivers G_IC, and one said touch processing unit T_IC is disposed between two said source drivers S_IC. In an embodiment of the invention, a center of the touch processing unit T_IC is aligned with a center line of the pixel region 106 and said center line is parallel to the data lines DL, but the invention is not limited thereto. In the present embodiment, a timing for performing a touch sensing and a timing for performing a display driving may be staggered so as to avoid signal interference. The gate driver G_IC, the source driver S_IC and the touch processing unit T_IC may be synchronized by a synchronizing signal. In other words, the touch processing unit T_IC may perform the touch sensing during a blank time between timepoints after a driving signal is outputted by the source driver S_IC and before a driving signal is outputted by the gate driver G_IC. Further, it is schematically illustrated in FIG. 1 that the gate driver G_IC, the source driver S_IC and the touch processing unit T_IC are electronic devices independent from each other, but the invention is not limited thereto. In other embodiments, any two or three of the above may be integrated into a single electronic device, so as to reduce circuits or wirings in the peripheral region 108. For instance, the source driver S_IC and the touch processing unit T_IC may be integrated into one single electronic device.

In the present embodiment, the pixel array substrate 100 may further include a plurality of dummy signal lines DM disposed in the pixel region 106 of the substrate 102. The dummy signal lines DM are parallel to the gate signal lines GTL, and potentials of the dummy signal lines DM and the gate signal lines GTL are equal. A total number of the dummy signal lines DM and the gate signal lines GTL may equal to ⅓ the number of the data lines DL, and the dummy signal lines DM and the gate signal lines GTL are commonly equidistantly distributed on the substrate 102. More specifically, in an example where one pixel contains three sub-pixels (e.g., a red sub-pixel, a green sub-pixel and a blue sub-pixel), one dummy signal line DM or one gate signal line GTL is disposed per three said data lines DL. In this way, capacitance parasitic environment near each pixel may be similar to the other, so as to improve a display quality. However, the invention is not limited thereto. In some embodiments, the total number of the dummy signal lines DM and the gate signal lines GTL may be equal to the number of the data lines DL, and the dummy signal lines DM and the gate signal lines GTL are commonly equidistantly distributed on the substrate 102. More specifically, only one of the dummy signal line DM and the gate signal line GTL is disposed per each data line DL. In this way, capacitance parasitic environment near each data line DL may be similar to the other, so as to improve the display quality.

The followings refer to FIG. 2. In the first embodiment of the invention, the number of the touch signal lines TL is less than the number of the gate signal lines GTL, and the touch signal lines TL and a part of the gate signal lines GTL may be respectively adjacent to the same data lines. For instance, with the active devices 104 in three adjacent columns taken as a group, the gate signal line GTL may be disposed between the adjacent groups and adjacent to the data line DL, and the dummy signal line DM may be disposed in the group and adjacent to the data line DL.

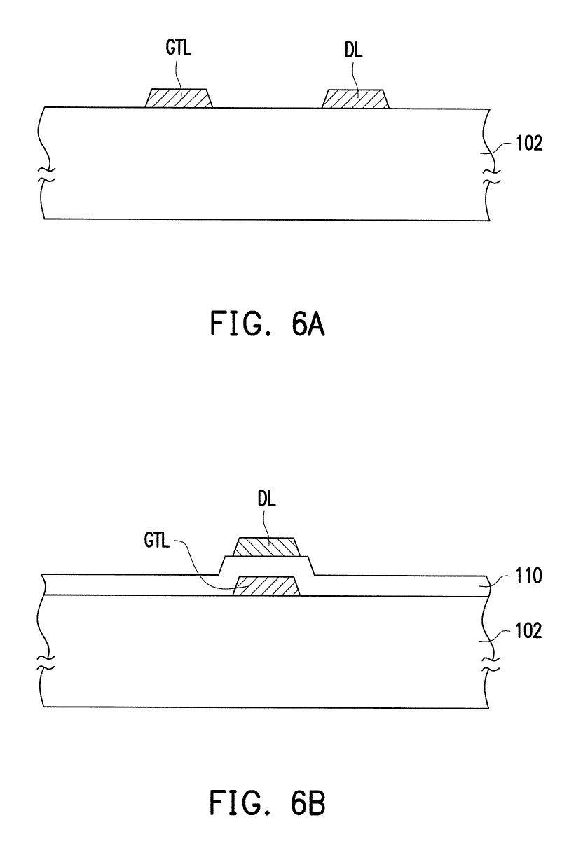

FIG. 6A and FIG. 6B are schematic diagrams for disposing gate signal lines and data lines according to an embodiment of the invention.

With reference to FIG. 6A, the gate signal line GTL and the data line DL (or the dummy signal line DM (not illustrated) and the data line DL) may be located on the same layer (e.g., located on the substrate 102) and electrically insulated from each other. Nonetheless, in terms of increasing an opening rate, as shown in FIG. 6B, the gate signal line GTL and the data line DL (or the dummy signal line DM (not illustrated) and the data line DL) may be respectively located on different layers (e.g., respectively located on the substrate 102 and in an insulation layer 110), and overlapping in a direction perpendicular to the substrate 102.

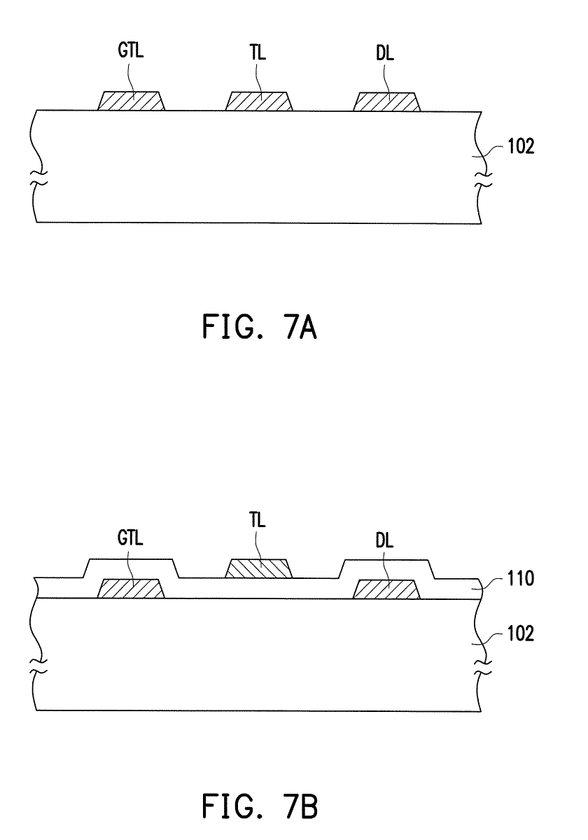

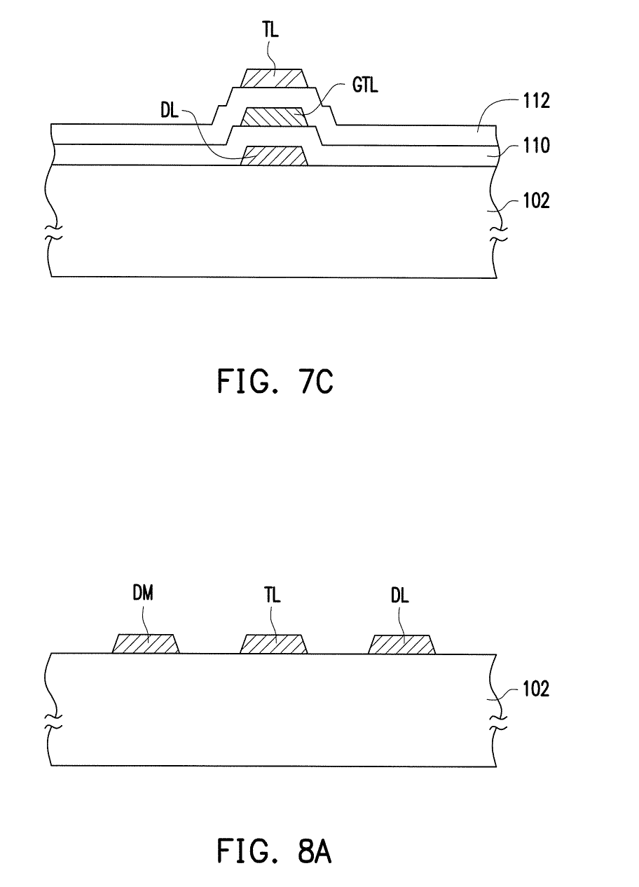

FIG. 7A to FIG. 7C are schematic diagrams for disposing gate signal lines, touch signal lines and data lines according to an embodiment of the invention.

The followings refer to FIG. 2 and FIG. 7A together. The touch signal line TL is, for example, disposed between n adjacent groups, where n is an integer greater than 1. The gate signal line GTL, the data line DL and the touch signal line TL may be located on the same layer (e.g., located on the substrate 102) and electrically insulated from each other. In terms of increasing an opening rate, it is more preferable that at least two of the gate signal line GTL, the data line DL and the touch signal line TL are located on the same layer, whereas the remaining one is disposed between said at least two in the direction perpendicular to the substrate 102. For example, as shown in FIG. 7B, the gate signal line GTL and the data line DL are located on the same layer (e.g., the substrate 102); the touch signal line TL is located on another layer (e.g., the insulation layer 110); and the touch signal line TL is disposed between the gate signal line GTL and the data line DL in the direction perpendicular to the substrate 102. Alternatively, as shown in FIG. 7C, the gate signal line GTL, the data line DL and the touch signal line TL are respectively located on different layers (e.g., respectively located on the substrate 102, the insulation layer 110 and an insulation layer 112) and overlapping in the direction perpendicular to the substrate 102.

FIG. 3 is a partial schematic diagram of a pixel array substrate in the second embodiment of the invention.

The followings refer to FIG. 3. A basic architecture of a pixel array substrate 300 of FIG. 3 is similar to a basic architecture of the pixel array substrate 100 of FIG. 2, and unless otherwise indicated, the specific description of FIG. 3 may refer to the first embodiment above. In the pixel array substrate 300, the touch signal lines TL and the gate signal lines GTL may be respectively adjacent to the different data lines DL. For instance, with the active devices 104 in three adjacent columns taken as a group, the gate signal line GTL may be disposed between the adjacent groups and adjacent to the data line DL, and the dummy signal line DM may be disposed in the group and adjacent to the data line DL. With the active devices 104 in m adjacent columns taken as a group where m is a positive integer not equal to 3, the touch signal TL may be disposed between the adjacent groups and adjacent to another data line DL.

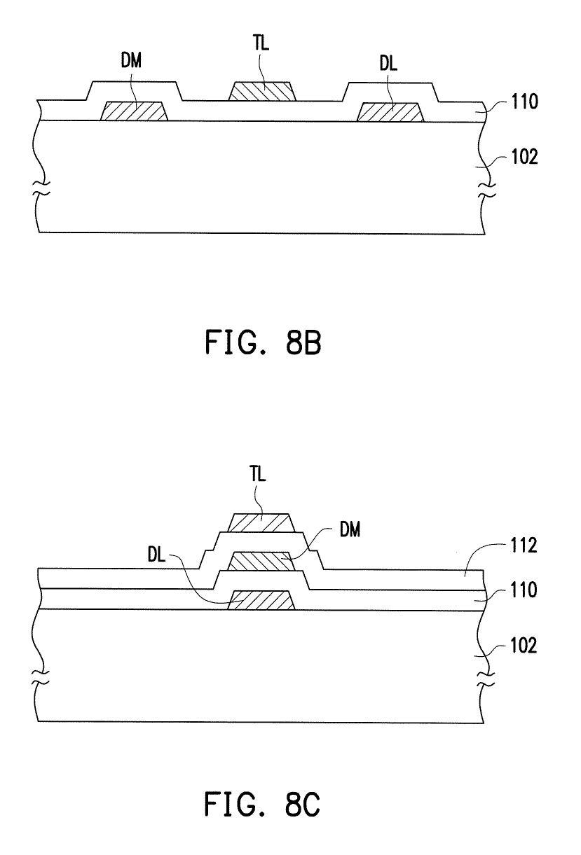

FIG. 8A to FIG. 8C are schematic diagrams for disposing dummy signal lines, touch signal lines and data lines according to an embodiment of the invention.

With reference to FIG. 8A, the touch signal line TL, the data line DL and the dummy signal line DM may be located on the same layer (e.g., located on the substrate 102) and electrically insulated from each other. In terms of increasing an opening rate, it is more preferable that at least two of the touch signal line TL, the data line DL and the dummy signal line DM are located on the same layer, whereas the remaining one is disposed between said at least two in the direction perpendicular to the substrate 102. For example, as shown in FIG. 8B, the dummy signal line DM and the data line DL are located on the same layer (e.g., the substrate 102); the touch signal line TL is located on another layer (e.g., the insulation layer 110); and the touch signal line TL is disposed between the dummy signal line DM and the data line DL in the direction perpendicular to the substrate 102. Alternatively, as shown in FIG. 8C, the touch signal line TL, the data line DL and the dummy signal line DM are respectively located on different layers (e.g., respectively located on the insulation layer 112, the substrate 102 and the insulation layer 110) and overlapping in the direction perpendicular to the substrate 102.

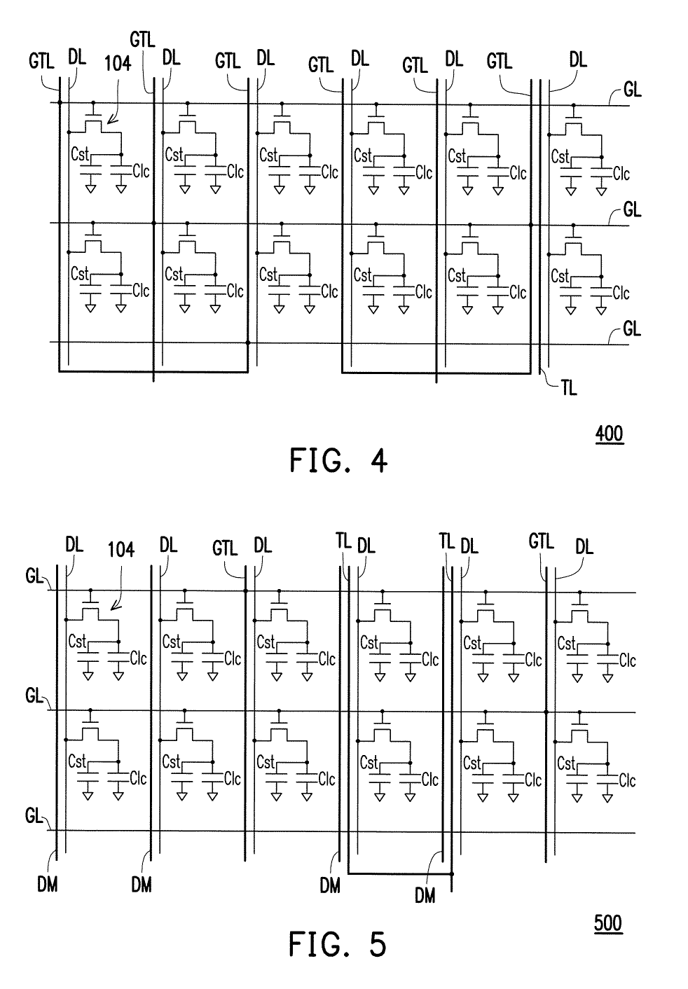

FIG. 4 is a partial schematic diagram of a pixel array substrate in the third embodiment of the invention.

The followings refer to FIG. 4. A basic architecture of a pixel array substrate 400 of FIG. 4 is similar to the basic architecture of the pixel array substrate 100 of FIG. 2, and unless otherwise indicated, the specific description of FIG. 4 may refer to the first embodiment above. In the pixel array substrate 400, the number of the gate signal lines GTL is equal to the number of the data lines DL, and a part of the gate signal lines GTL may be connected to each other in the peripheral region 108 before being connected to the gate driver G_IC so as to reduce wirings for connecting to the gate driver G_IC. FIG. 4 schematically illustrates a condition in which the three adjacent gate signal lines GTL are connected together in the peripheral region 108 where illustration for parts connected to the gate driver G_IC is omitted. In addition, with three adjacent gate signal lines GTL connected in the peripheral region 108 taken as a group, the touch signal line TL may be disposed between k adjacent groups where k is an integer greater than 1. In other words, the touch signal line TL and a part of the gate signal lines GTL may be respectively adjacent to the same data line.

FIG. 5 is a partial schematic diagram of a pixel array substrate in the fourth embodiment of the invention.

The followings refer to FIG. 5. A basic architecture of a pixel array substrate 500 of FIG. 5 is similar to the basic architecture of the pixel array substrate 300 of FIG. 3, and unless otherwise indicated, the specific description of FIG. 5 may refer to the first embodiment above. In the pixel array substrate 500, a part of the touch signal lines TL may be connected to each other in the peripheral region 108 before being connected to the touch processing unit T_IC. For instance, with the active devices 104 in three adjacent columns taken as a group, the gate signal line GTL may be disposed between the adjacent groups and adjacent to the data line DL. The touch signal line TL may be disposed between the adjacent gate signal lines GTL and connected to each other in the peripheral region 108 before being connected to the touch processing unit T_IC so as to reduce wirings for connecting to the touch processing unit T_IC. FIG. 5 schematically illustrates a condition in which the two adjacent touch signal lines TL are connected together in the peripheral region 108 where illustration for parts connected to the touch processing unit T_IC is omitted. In the present embodiment, the touch signal lines TL and the gate signal lines GTL may be respectively adjacent to the different data lines DL.

In summary, in the pixel array substrate according to the embodiments of the invention, the gate driver, the source driver and the touch processing unit are disposed in the peripheral region and located on the same side of the pixel region, and the portions of the data lines, the gate signal lines and the touch signal lines within the pixel region are parallel to each other. Accordingly, other than the effectiveness that the touch processing unit and the touch signal lines can be integrated into the processing unit, the opening rate and the narrow border may also be improved. According to some embodiments, the data lines, the gate signal lines and the touch signal lines may be respectively located on the different layers, or any two of the gate driver, the source driver and the touch processing unit may be integrated, so as to realize an ultra narrow border.

Lastly, it should be noted that, the above embodiments merely serve as examples in the present embodiment, the invention is not limited thereto. Despite that the invention has been described with reference to above embodiments, it will be apparent to those skilled in the art that various modifications and variations can be made to the structure of the technical content disclosed in above embodiments of the invention without departing from the scope or spirit of the invention. In view of the foregoing, it is intended that the invention cover modifications and variations of this invention provided they fall within the scope of the following claims and their equivalents.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A pixel array substrate, comprising:
a substrate, divided into a pixel region and a peripheral region;
a plurality of active devices, disposed in the pixel region of the substrate;
a plurality of gate lines and a plurality of data lines, disposed on the substrate, the gate lines and the data lines being electrically connected to the corresponding active devices, respectively;
a gate driver, a source driver and a touch processing unit, disposed in the peripheral region of the substrate, and located on a same side of the pixel region, wherein the data lines are electrically connected to the source driver;
a plurality of gate signal lines, disposed on the substrate, and electrically connecting the corresponding gate lines to the gate driver;
a plurality of touch pads, disposed in the pixel region of the substrate; and
a plurality of touch signal lines, disposed on the substrate, and electrically connecting the corresponding touch pads to the touch processing unit, wherein portions of the data lines, the gate signal lines and the touch signal lines within the pixel region are parallel to each other.

2. The pixel array substrate according to claim 1, wherein the touch processing unit is disposed between two said source drivers, and the source driver is disposed between two said gate drivers.

3. The pixel array substrate according to claim 1, wherein a number of the gate signal lines is less than a number of the data lines.

4. The pixel array substrate according to claim 1, wherein a number of the touch signal lines is less than a number of the gate signal lines.

5. The pixel array substrate according to claim 1, wherein the touch signal lines and the gate signal lines are respectively adjacent to the different data lines.

6. The pixel array substrate according to claim 1, wherein the touch signal lines and a part of the gate signal lines are respectively adjacent to the same data lines.

7. The pixel array substrate according to claim 1, wherein a part of the gate signal lines are connected each other in the peripheral region before being connected to the gate driver.

8. The pixel array substrate according to claim 1, wherein a part of the touch signal lines are connected to each other in the peripheral region before being connected to the touch processing unit.

9. The pixel array substrate according to claim 1, further comprising a plurality of dummy signal lines, disposed on the substrate, and parallel to the gate signal lines, wherein a total number of the dummy signal lines and the gate signal lines is equal to a number of the data lines, and the dummy signal lines and the gate signal lines are commonly equidistantly distributed on the substrate.

10. The pixel array substrate according to claim 1, wherein the source driver and the touch processing unit are integrated into a single electronic device.

11. The pixel array substrate according to claim 1, wherein the data lines, the gate signal lines and the touch signal lines are respectively located on different layers.

12. The pixel array substrate according to claim 1, wherein at least two of the data lines, the gate signal lines and the touch signal lines are located on a same layer.

13. The pixel array substrate according to claim 1, wherein the gate driver, the source driver and the touch processing unit are synchronized by a synchronizing signal.
